(19) United States
(12) Patent Application Publication
(10) Pub. No.: US 2015/0044889 A1
(43) Pub. Date: Feb. 12, 2015

(54) ELECTRICAL CONNECTOR AND ASSEMBLY OF THE ELECTRICAL CONNECTOR AND A CIRCUIT BOARD

(71) Applicants: LITE-ON ELECTRONICS (GUANGZHOU) LIMITED, Guangzhou (CN); LITE-ON TECHNOLOGY CORP., Taipei (TW)

(72) Inventors: CHUNG-FU WANG, TAIPEI 11492 (TW); NIEN-HUNG YAO, TAIPEI 11492 (TW); HSIN-YU YANG, TAIPEI 11492 (TW); YU-SHAN KAO, TAIPEI 11492 (TW)

(21) Appl. No.: 14/318,851

(22) Filed: Jun. 30, 2014

(30) Foreign Application Priority Data
Aug. 9, 2013 (CN) 201320486960.4

(51) Int. Cl. H01R 4/02; H05K 1/11; H01R 12/57

(52) U.S. Cl. CPC H01R 4/02; H01R 12/57; H05K 1/11
USPC 439/83; 439/876

(57) ABSTRACT

An electrical connector includes an insulating body having a bottom surface, a receiving groove formed in the bottom surface, and at least one support block projecting downwardly from the bottom surface for connection with a circuit board and cooperating with the bottom surface to define a venting space that communicates with the receiving groove and a solder hole in the circuit board. A conductive terminal includes a first positioning portion extending into and positioned in the receiving groove, and a second positioning portion connected to the first positioning portion and extending through the venting space and adapted to be positioned in the solder hole.

### CROSS REFERENCE TO RELATED APPLICATION

This application claims priority of Chinese Patent Application No. 201320486960.4, filed on Aug. 9, 2013, the disclosure of which is incorporated herein by reference.

### BACKGROUND OF THE INVENTION

1. Field of the Invention

This invention relates to an electrical connector, more particularly to an electrical connector that is in contact with a circuit board through a support block and an assembly of the electrical connector and the circuit board.

2. Description of the Related Art

A conventional board in connector comprises an insulating body, and a plurality of conductive terminals disposed on the insulating body. To solder and fix the board in connector to the circuit board, the conductive terminals of the board in connector are first inserted into a plurality of solder holes of the circuit board, respectively, such that a bottom surface of the insulating body abuts flatly against a top surface of the circuit board. An assembly of the board in connector and the circuit board is then passed through a tin furnace, so that liquid tin flows into each solder hole. After the liquid tin is solidified, each of the conductive terminals is soldered to the respective solder hole.

Because the bottom surface of the insulating body abuts flatly against the top surface of the circuit board, the following problems may occur during the tinning process in the tin furnace:

1. Because a top end of each solder hole is closed by the insulating body, the top end of each solder hole cannot communicate with the ambient atmosphere. When the liquid tin flows into each solder hole through a bottom end thereof, the liquid tin cannot completely fill up each solder hole, so that the amount of liquid tin for soldering each conductive terminal in the respective solder hole may be insufficient.

2. Because each conductive terminal that protrudes from a bottom surface of the circuit board is long, each two adjacent ones of the conductive terminals are likely to be connected to each other after the liquid tin is solidified, thereby possibly causing a short circuit.

3. Because the bottom surface of the insulating body is in contact with the high-temperature liquid tin for a long time, the insulating body is likely to melt and get damaged.

4. Based on the aforesaid phenomenon, the assembly and the soldering quality of the board in connector and the circuit board are easily affected, even causing waste of maintenance time during machine production and increase in losses and costs.

### SUMMARY OF THE INVENTION

Therefore, an object of the present invention is to provide an electrical connector that is capable of increasing the amount of liquid tin for soldering a conductive terminal in a solder hole of a circuit board.

Another object of the present invention is to provide an electrical connector that is capable of preventing interconnection between two adjacent ones of conductive terminals during a tinning process in a tin furnace.

Still another object of the present invention is to provide an electrical connector that is capable of preventing an insulating body from being melted and damaged by high-temperature liquid tin during the tinning process in the tin furnace.

According to one aspect of this invention, an electrical connector for mounting on a circuit board having a solder hole comprises an insulating body and a conductive terminal. The insulating body includes a bottom surface, a receiving groove formed in the bottom surface, and at least one support block projecting downwardly from the bottom surface for connection with the circuit board. The bottom surface and the support block cooperatively define a venting space that communicates with the receiving groove and that is adapted to communicate with the solder hole. The conductive terminal includes a first positioning portion extending into and positioned in the receiving groove, and a second positioning portion connected to the first positioning portion and extending through the venting space and adapted to be positioned in the solder hole.

Yet another object of the present invention is to provide an assembly of an electrical connector and a circuit board that is capable of increasing the amount of liquid tin for soldering a conductive terminal in a solder hole of the circuit board.

Still yet another object of the present invention is to provide an assembly of an electrical connector and a circuit board that is capable of preventing interconnection between two adjacent ones of conductive terminals during a tinning process in a tin furnace.

A still further object of the present invention is to provide an assembly of an electrical connector and a circuit board that is capable of preventing an insulating body from being melted and damaged by high-temperature liquid tin during the tinning process in the tin furnace.

According to another aspect of this invention, an assembly of an electrical connector and a circuit board comprises a circuit board and an electrical connector. The circuit board has at least one solder hole. The electrical connector includes an insulating body and at least one conductive terminal. The insulating body includes a bottom surface, at least one receiving groove formed in the bottom surface, and at least one support block projecting downwardly from the bottom surface and connected to the circuit board. The bottom surface and the support block cooperatively define a venting space that communicates with the receiving groove and the solder hole. The conductive terminal includes a first positioning portion extending into and positioned in the receiving groove, and a second positioning portion connected to the first positioning portion and extending through the venting space and positioned in the solder hole.

The efficiency of this invention resides in that the amount of liquid tin for soldering each conductive terminal on the respective solder hole can be effectively increased, and direct connection of the resilient arms of each two adjacent ones of the conductive terminals after the liquid tin is solidified can be effectively prevented to thereby prevent the occurrence of short circuit. Further, the liquid tin is prevented from directly contacting the bottom surface of the insulating body when it flows out of the top end of each solder hole, thereby preventing the insulating body from being in contact with and being damaged by the high-temperature liquid tin.

### BRIEF DESCRIPTION OF THE DRAWINGS

Other features and advantages of the present invention will become apparent in the following detailed description of the preferred embodiment with reference to the accompanying drawings, of which:

FIG. 1 is a perspective view of an assembly of an electrical connector and a circuit board according to the preferred embodiment of the present invention;

FIG. 2 is an exploded perspective view of the preferred embodiment;

FIG. 3 is a bottom perspective view of an insulating body of the preferred embodiment;

FIG. 4 is a schematic top view of the preferred embodiment;

FIG. 5 is a sectional view of the preferred embodiment taken along line V-V of FIG. 4; and

FIG. 6 is a sectional view of the preferred embodiment taken along line VI-VI of FIG. 1.

### DETAILED DESCRIPTION OF THE PREFERRED EMBODIMENT

Before the present invention is described in greater detail, it should be noted herein that like elements are denoted by the same reference numerals throughout the disclosure.

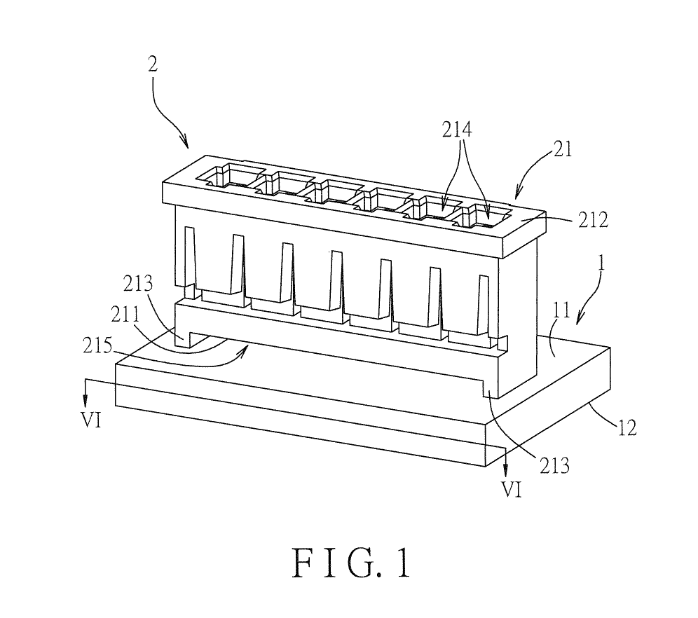

FIG. 1 illustrates the preferred embodiment of an assembly of an electrical connector and a circuit board according to the present invention. The assembly is suitable for use in a power supply, and comprises a circuit board 1, and an electrical connector 2 mounted on the circuit board 1.

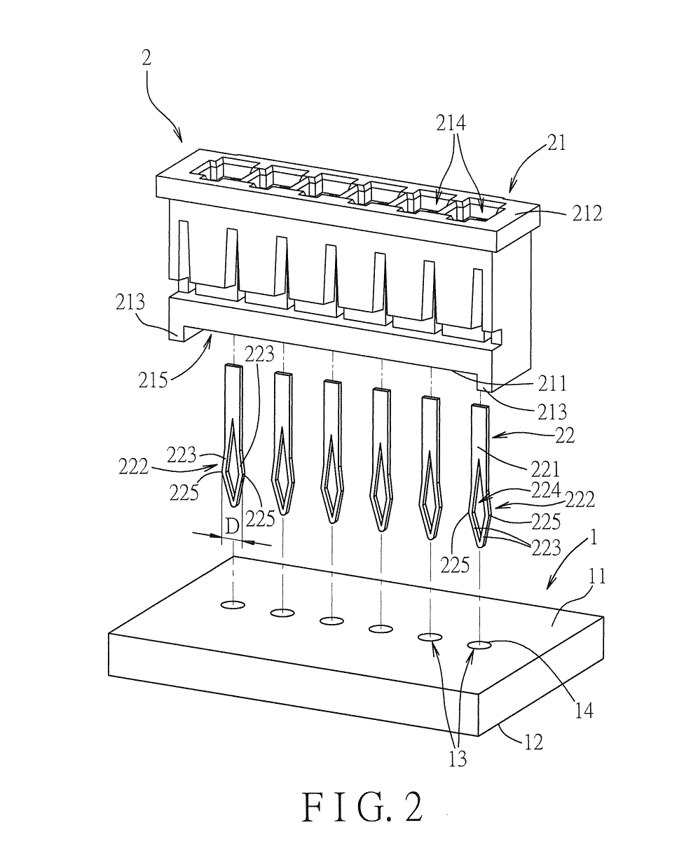

Referring to FIGS. 2 to 4, the circuit board 1 includes a top surface 11, a bottom surface 12, and at least one solder hole 13 extending through the top and bottom surfaces 11, 12. In this embodiment, a plurality of the solder holes 13 are exemplified. The electrical connector 2 is a board in connector, and includes an insulating body 1 and at least one conductive terminal 22. In this embodiment, a plurality of the conductive terminals 22 are exemplified. The insulating body 21 includes a bottom surface 211, a top surface 212, at least one support block 213 projecting downwardly from the bottom surface 211 to abut against the top surface 11 of the circuit board 1, and at least one receiving groove 214 extending through the top and bottom surfaces 212, 211. In this embodiment, a plurality of the receiving grooves 214 are exemplified. The bottom surface 211 and the support block 213 cooperatively define a venting space 215 that communicates with the receiving grooves 214 and the solder holes 13. Each conductive terminal 22 includes a first positioning portion 221 extending into and positioned in a respective one of the receiving grooves 214, and a second positioning portion 222 connected to the first positioning portion 221. The second positioning portion 222 of each conductive terminal 22 extends through the venting space 215 into a respective one of the solder holes 13 so as to be positioned therein.

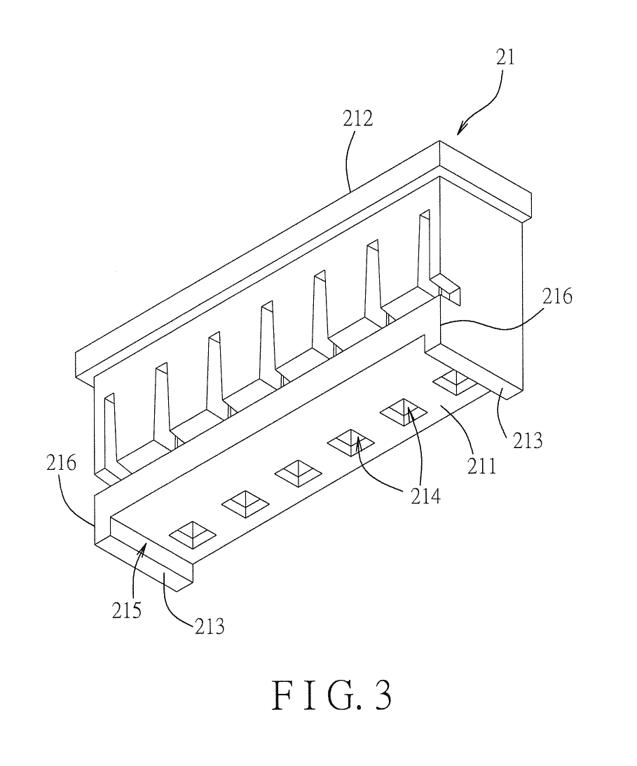

As shown in FIGS. 3 to 5, the bottom surface 211 of the insulating body 21 is rectangular, and has two opposite short sides 216. In this embodiment, the insulating body 21 includes two support blocks 213 that project downwardly and respectively from the short sides 216. The receiving grooves 214 are arranged spaced apart from each other along the length of the bottom surface 211, and are located the support blocks 213. Through the presence of the support blocks 213, when the support blocks 213 abut against the top surface 11 of the circuit board 1, the venting space 215 can communicate with an external environment of the insulating body 21 at a large range. When the circuit board 1 passes through a tin furnace, high-temperature liquid tin flows from the bottom surface 12 of the circuit board 1 into the solder holes 13, and pushes air in each solder hole 13 into the venting space 215. Air is smoothly discharged out into the external environment of the insulating body 21 via the venting space 215. As such, the liquid tin can smoothly and completely fill each solder hole 13, thereby effectively increasing the amount of liquid tin for soldering each conductive terminal 22 on the respective solder hole 13. It is worth to mention that the number of each of the receiving groove 214, the conductive terminal 22 and the solder hole 13 may be one depending on actual requirement, and is not limited to the disclosed number of this embodiment.

More specifically, in this embodiment, each support block 213 is rectangular and has a length equal to that of the respective short side 216, so that a contact area between each support block 213 and the top surface 11 of the circuit board 1 is large. Thus, the insulating body 21 can be stably positioned on the top surface 11 of the circuit board 1 through the support blocks 213. Alternatively, the length of each support block 213 may be smaller than that of the respective short side 216.

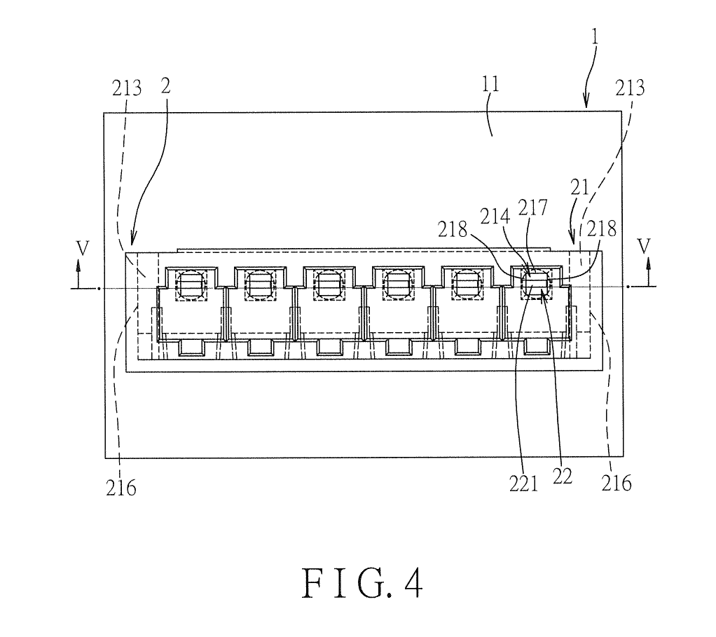

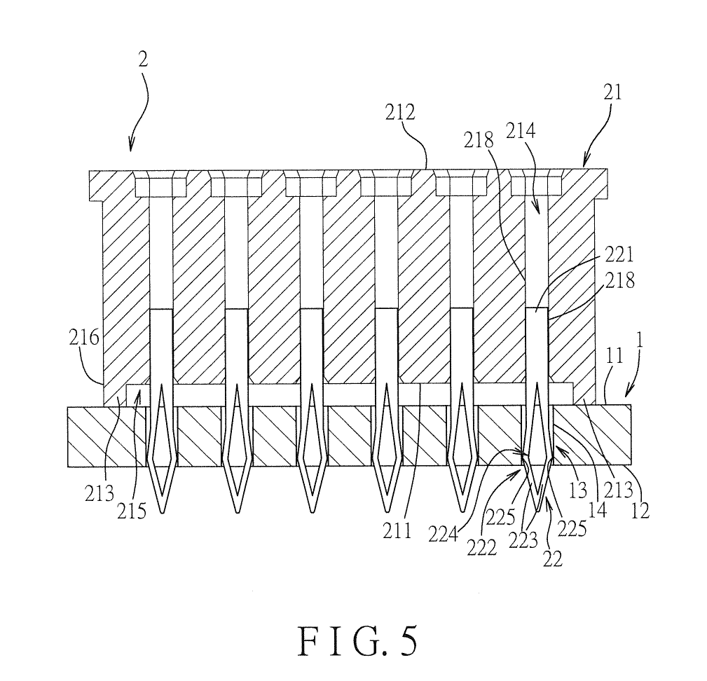

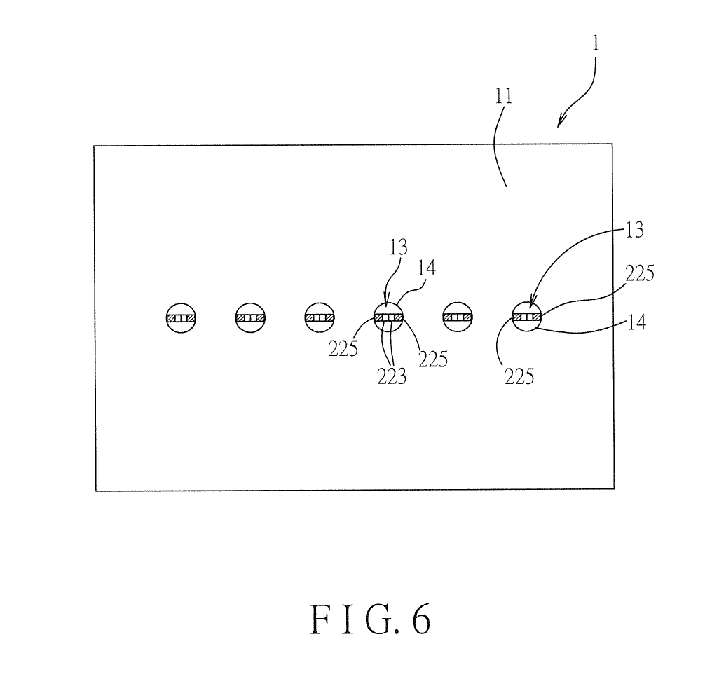

Referring to FIG. 6, in combination with FIGS. 4 and 5, each receiving groove 214 in the insulating body 21 is defined by a generally rectangular groove wall 217. The groove wall 217 includes left and right groove sidewalls 218. The first positioning portion 221 of each conductive terminal 22 has left and right sides respectively abutting against the left and right groove sidewalls 218 of the corresponding groove wall 217, so that each conductive terminal 22 can be stably positioned in the respective receiving groove 214. The second positioning portion 222 of each conductive terminal 22 is connected to a bottom end of the first positioning portion 221, and includes two resilient arms 223. The resilient arms 223 are connected to each other to form a closed loop defining an opening 224. Alternatively, the resilient arms 223 may be configured to be spaced apart from each other depending on actual requirement, so that bottom ends of the resilient arms 223 form an opening therebetween. Moreover, the number of the resilient arm 223 may be one depending on the requirement. Each resilient arm 223 has a sharp abutment end 225. The opening 224 serves to provide a space needed by the abutment ends 225 of the resilient arms 223 when they are pressed and deformed inwardly so as to move close to each other during insertion of the second end portion 222 of each conductive terminal 22 into the corresponding solder hole 13. Each solder hole 13 in the circuit board 1 is circular, and is defined by a hole wall 14. Through abutment of the abutment ends 225 of the resilient arms 223 of each conductive terminal 22 with the hole wall 14 of the corresponding solder hole 13, the second positioning portion 222 of each conductive terminal 22 can be securely positioned in the respective solder hole 13.

With reference to FIGS. 2, 5 and 6, to solder the electrical connector 2 to the circuit board 1, each conductive terminal 22 of the electrical connector 2 is first brought to align with a top side of the respective solder hole 13, after which it is inserted downwardly into the respective solder hole 13. Because a distance (D) between the abutment ends 225 of each conductive terminal 22 is slightly larger than a diameter of the corresponding solder hole 13, when the abutment ends 225 of the resilient arms 25 abut against the hole wall 14, the resilient arms 223 are squeezed by the hole wall 14 to deform inwardly so as to move close to each other, so that the resilient arms 223 can easily extend into the corresponding solder hole 13. When the support blocks 213 of the electrical connector 2 abut against the top surface 11 of the circuit board 1, the electrical connector 2 cannot be moved further downward. At this time, with the abutment ends 225 of the resilient arms 223 abutting against two opposite sides of the hole wall 14, the electrical connector 2 is stably positioned on the circuit board 1.

Referring once again to FIGS. 1 and 5, afterwards, the assembly of the electrical connector 2 and the circuit board 1 is passed through the tin furnace. Because the insulating body 21 is mounted on the top surface 11 of the circuit board 1 through the support blocks 213, the venting space 215 defined by the bottom surface 211 and the support blocks 213 can communicate with the solder holes 13 in the circuit board 1. As such, when high-temperature liquid tin flows from the bottom surface 12 of the circuit board 1 into each solder hole 13, the liquid tin can push air in each solder hole 13 into the venting space 215, and from the venting space 215, air is smoothly discharged out into the external environment of the insulating body 21. Hence, the liquid tin can smoothly and completely fill each solder hole 13, thereby effectively increasing the amount of liquid tin for soldering each conductive terminal 22 on the respective solder hole 13. After the liquid tin in each solder hole 13 is solidified, the second positioning portion 222 of each conductive terminal 22 is soldered and fixed in the corresponding solder hole 13 of the circuit board 1.

Because the insulating body 21 is mounted on the top surface 11 of the circuit board 1 through the support blocks 213, the bottom surface 211 of the insulating body 21 is lifted up at a suitable distance, so that the lengths of the two resilient arms 223 of each conductive terminal 22 which protrude out of the bottom surface 12 of the circuit board 1 can be shortened. This can effectively reduce direct connection of the resilient arms 23 of each two adjacent ones of the conductive terminals 22 after the liquid tin is solidified, thereby preventing the occurrence of short circuit. Further, because a suitable distance is maintained between the bottom surface 211 of the insulating body 21 and the top surface 11 of the circuit board 1, the liquid tin is prevented from directly contacting the bottom surface 211 of the insulating body 21 when it flows out of the top end of each solder hole 13. Hence, the insulating body 21 is prevented from being in contact with and being damaged by the high-temperature liquid tin.

In sum, because the insulating body 21 is mounted on the top surface 11 of the circuit board 1 through the support blocks 213, during passing of the assembly of the circuit board 1 and the electrical connector 2 through the tin furnace, liquid tin can push air in each solder hole 13 into the venting space 215, and from the venting space 215, air is smoothly discharged out into the external environment of the insulating body 21. As such, the liquid tin can smoothly and completely fill each solder hole 13, thereby effectively increasing the amount of liquid tin for soldering each conductive terminal 22 on the respective solder hole 13. Further, because a suitable distance is maintained between the bottom surface 211 of the insulating body 21 and the top surface 11 of the circuit board 1, the lengths of the two resilient arms 223 of each conductive terminal 22 which protrude out of the bottom surface 12 of the circuit board 1 can be shortened. This can effectively prevent direct connection of the resilient arms 23 of each two adjacent ones of the conductive terminals 22 after the liquid tin is solidified, thereby preventing the occurrence of short circuit. Moreover, the liquid tin is prevented from directly contacting the bottom surface 211 of the insulating body 21 when it flows out of the top end of each solder hole 13, thereby prevent ing the insulating body 21 from being in contact with and being damaged by the high-temperature liquid tin. Through this, the assembly of and the soldering quality between the circuit board 1 and the electrical connector can be significantly enhanced, so that waste of maintenance time during machine production and the increase of cost can be prevented. Therefore, the objects of this invention can be achieved.

While the present invention has been described in connection with what is considered the most practical and preferred embodiment, it is understood that this invention is not limited to the disclosed embodiment but is intended to cover various arrangements included within the spirit and scope of the broadest interpretation so as to encompass all such modifications and equivalent arrangements.

What is claimed is:

1. An electrical connector for mounting on a circuit board having a solder hole, said electrical connector comprising:
an insulating body including a bottom surface, a receiving groove formed in said bottom surface, and at least one support block projecting downwardly from said bottom surface for connection with the circuit board, said bottom surface and said support block cooperatively defining a venting space that communicates with said receiving groove and that is adapted to communicate with the solder hole; and
a conductive terminal including a first positioning portion extending into and positioned in said receiving groove, and a second positioning portion connected to said first positioning portion and extending through said venting space and adapted to be positioned in the solder hole.

2. The electrical connector as claimed in claim 1, wherein said bottom surface of said insulating body has two opposite short sides, said insulating body including two said support blocks that project downwardly and respectively from said short sides, said insulating body further including a top surface, said receiving groove extending through said bottom and top surfaces and being located between said support blocks.

3. The electrical connector as claimed in claim 2, wherein each of said support blocks has a length less than or equal to that of a respective one of said short sides.

4. The electrical connector as claimed in claim 1, wherein said second positioning portion of said conductive terminal includes at least one resilient arm to facilitate insertion into and positioning in the solder hole.

5. The electrical connector as claimed in claim 4, wherein said second positioning portion of said conductive terminal includes two said resilient arms that form an opening therebetween to facilitate insertion into and positioning in the solder hole.

6. The electrical connector as claimed in claim 4, wherein said second positioning portion of said conductive terminal includes two said resilient arms that are connected to each other to form a closed loop defining an opening to facilitate insertion into and positioning in the solder hole.

7. An assembly of an electrical connector and a circuit board comprising:
a circuit board having at least one solder hole; and
an electrical connector including
an insulating body including a bottom surface, at least one receiving groove formed in said bottom surface, and at least one support block projecting downwardly from said bottom surface and connected to said circuit board, said bottom surface and said support block cooperatively defining a venting space that communicates with said receiving groove and said solder hole; and
at least one conductive terminal including a first positioning portion extending into and positioned in said receiving groove, and a second positioning portion connected to said first positioning portion and extending through said venting space and positioned in said solder hole.

8. The assembly as claimed in claim 7, wherein said bottom surface of said insulating body has two opposite short sides, said insulating body including two said support blocks that project downwardly and respectively from said short sides, said insulating body further including a top surface, said receiving groove extending through said bottom and top surfaces and being located between said support blocks.

9. The assembly as claimed in claim 8, wherein each of said support blocks has a length less than or equal to that of a respective one of said short sides.

10. The assembly as claimed in claim 7, wherein said second positioning portion of said conductive terminal includes at least one resilient arm to facilitate insertion into and positioning in said solder hole.

11. The assembly as claimed in claim 10, wherein said second positioning portion of said conductive terminal includes two said resilient arms that form an opening therebetween to facilitate insertion into and positioning in said solder hole.

12. The assembly as claimed in claim 10, wherein said second positioning portion of said conductive terminal includes two said resilient arms that are connected to each other to form a closed loop defining an opening to facilitate insertion into and positioning in said solder hole.

13. The assembly as claimed in claim 7, wherein said circuit board has a plurality of said solder holes, said insulating body including a plurality of said receiving grooves formed in said bottom surface, said venting space communicating with said solder holes and said receiving grooves, said electrical connector including a plurality of said conductive terminals, said first positioning portion of each of said conductive terminals extending into and positioned in a respective one of said receiving grooves, said second positioning portion of each of said conductive terminals extending through said venting space and being positioned in a respective one of said solder holes.

14. The assembly as claimed in claim 13, wherein said bottom surface of said insulating body has two opposite short sides, said insulating body including two said support blocks that project downwardly and respectively from said short sides, said insulating body further including atop surface, said receiving groove extending through said bottom and top surfaces and being located between said support blocks.

15. The assembly as claimed in claim 14, wherein each of said support blocks has a length less than or equal to that of a respective one of said short sides.

16. The assembly as claimed in claim 13, wherein said second positioning portion of said conductive terminal includes at least one resilient arm to facilitate insertion into and positioning in said solder hole.

17. The assembly as claimed in claim 16, wherein said second positioning portion of said conductive terminal includes two said resilient arms that form an opening therebetween to facilitate insertion into and positioning in said solder hole.

18. The assembly as claimed in claim 16, wherein said second positioning portion of said conductive terminal includes two said resilient arms that are connected to each other to form a closed loop defining an opening to facilitate insertion into and positioning in said solder hole.
